(19) United States
(12) Patent Application Publication
(10) Pub. No.: US 2016/0003871 A1
(43) Pub. Date: Jan. 7, 2016

(54) Contactless Device for Characterising An Electric Signal

(71) Applicant: SMART IMPULSE, Chatenay Malabry Cedex (FR)

(72) Inventors: Dorian Tourin-Lebret, Sceaux (FR); Thibault Toledano, Taverny (FR)

(21) Appl. No.: 14/771,601

(22) PCT Filed: Feb. 25, 2014
(86) PCT No.: PCT/FR2014/050400

§ 371 Date: Aug. 31, 2015

(30) Foreign Application Priority Data
Mar. 5, 2013 (FR) 1351934

(51) Int. Cl. G01R 15/18; G01R 19/04; G01R 21/06

(52) U.S. Cl. CPC G01R 15/18; G01R 21/06; G01R 19/04

(57) ABSTRACT

A contactless device for characterising the electrical signal passing through an electrical conductor, comprising an inductive electromagnetic coupling means able to surround the conductor, the inductive electromagnetic coupling means further comprising means for short-circuiting the output of the inductive electromagnetic coupling means, the output being connected to an electronic circuit for measuring the potential difference with respect to a floating earth configured to deliver a signal representing the voltage between the segment of the conductor passing through the device, and a fixed potential reference.

### BACKGROUND

The present invention relates to the characterisation of the electrical signal flowing in a conductor, for various applications, and in particular for characterising the electrical consumption of a building.

More particularly, the invention relates to the field of contactless sensors for performing such characterisations, on a conductor that remains live and is not interrupted, even at the time of positioning the sensor.

For applications for characterising the electrical consumption of a building, the invention aims to determine the relative proportion of each type of equipment in the total consumption, with a single measuring point, with algorithms using current measurements made at a single point on an electrical installation, independently of its distribution architecture. In doing this, they do not provide information on the location of the equipment functioning since the signal captured does not differ according to the path traveled by the energy.

In order to provide supplementary information on consumption by zone, the patentee has developed an electricity meter having the following advantages:
Low cost
Non-intrusive
Hybrid: measurement of current and power factor
Communicating

In more general terms, such a meter can be used individually to measure the consumption of a subnetwork of an electrical installation.

The invention concerns particularly contactless electrical sensors interacting with a conductor by electromagnetic induction.

Inductive sensors consisting of an induction loop that can be placed around an electrical conductor and providing a signal representing the electrical current, by application of the Maxwell effect, are known in the prior art.

Systems capable of connecting to current sensors to determine the consumption passing through the cable on which they are placed are known in particular.

The American patent application US 2011/074382 presents a contactless current sensor having the advantage of computing the electrical energy consumed by means of a voltage measurement made by contact with the electrical conductor or conductors studied. The device is supplied by conversion of the energy captured by the galvanic connection with the live conductor.

This solution makes it possible to know the precise electrical consumption, without any assumption on the voltage, but requires tedious wiring.

The international patent application WO 2011/33548 presents a method for measuring the voltage of a contactless conductor using the electrical field radiated by the live conductor, the amplitude of the voltage of the conductor being studied is deduced from the amplitude of the voltage at the terminals of the pair of armatures forming a capacitor with known properties.

This solution makes it possible to measure the voltage of a conductor using a made-to-measure device.

The American patent application US 2012/0074929 presents an energy meter measuring the current without contact and the voltage by contact, and then transmitting the measured data by a wireless communication mode.

This solution makes it possible to measure the electrical consumption of an installation and to transmit the information remotely, the wiring being limited to the connection to the electrical network.

The European patent application EP 1684080 presents a current sensor suited to busbar sets, having the particularity of finding its supply source by capturing the energy conveyed by the magnetic field radiated by the conductive bar on which it is placed.

This solution autonomously provides a current measurement and the transmission of information wirelessly, but requires a made-to-measure mechanical design and many magnetic components to provide its function.

The patent application US 2005/275397 is also known, describing systems and methods for controlling the power in a conductor.

A flexible printed circuit comprises multiple layers including a voltage-detection layer, a winding and an earthing layer. The winding surrounds a conductor when the flexible printed circuit is coiled around the conductor. The winding generates a voltage that can be integrated in order to determine a current in the conductor. When the flexible printed circuit is wound around the conductor, the voltage-detection layer is as close as possible to the conductor. The voltage-detection layer forms a capacitor with the conductor. By using an adjustable capacitive voltage divider, the voltage of the conductor can be determined from a voltage signal received from the voltage-detection layer.

The international patent application WO 02097454 describes a three-phase voltage detector with active cancellation of crosstalk. The active crosstalk cancellation is achieved by means of a capacitive voltage divider for each of the phases of the system. A measurement of the voltage is obtained for the required phase and for each additional phase in the system. For each of the additional phases a product is calculated by multiplying the voltage measurement of each of the additional phases by a corresponding predetermined constant, and then said product is subtracted from the voltage measurement of the required phase.

The East German patent DD 130693 is also known, relating to a transformer comprising means for short-circuiting the output.

The solutions of the prior art having non-intrusive measurement means provide information representing the current but not the voltage, unless two complementary sensors are associated, as proposed in the solution described in the patent application US 2005/0275397.

The contactless measurement of the voltage conjointly, in order to characterise a signal, requires a very particular design based on capacitors, to provide information relating to the very approximate amplitude.

Moreover, all the solutions described in the prior art require an absolute potential reference frame, involving a physical connection to earth. These sensors of the prior art are therefore not “contactless” sensors and provide relevant information only when they are electrically connected to earth or to a stable potential reference frame. This is not always possible, or at least easy, since the location of the sensor does not always make it possible to find an electrical point constituting such a stable reference frame.

This means that, if the installer of the sensor uses as an earth a potential reference frame that is not really stable, the data supplied by the sensors of the prior art are erroneous.

The documents of the prior art cited and in particular the application WO 2992/097454 are intended for characterising the electrical signal in very-high-voltage lines. For such applications, there always exists an earthing point close by providing an absolute potential reference frame.

### SUMMARY

The invention proposed sets out to define a system for exploiting the signals provided by current transformers for measuring the consumption of the electrical network being studied without requiring any additional wiring and not requiring connection to a potential reference frame.

In order to remedy the drawbacks of the prior art, the invention relates, according to its most general acceptance, a contactless device for characterising the electrical signal passing through an electrical conductor, comprising an inductive electromagnetic coupling means able to surround said conductor, characterised in that it further comprises means for short-circuiting the output of said inductive coupling means, said output being connected to an electronic circuit for measuring the potential difference with respect to a floating earth in order to deliver a signal representing the voltage between the segment of said conductor passing through the device, and a fixed potential reference.

The device has no means for connection to a potential reference, and in particular does not require a connection to earth.

The inductive electromagnetic coupling means consists of a ferrite torus surrounding a conductor the electrical signal of which it is sought to characterise. This torus is itself surrounded by a coil, the two ends of which constitute the outputs connected to the electrical circuit.

The torus may consist of two connectable parts in order to facilitate coupling around a conductor without it being necessary to cut the conductor to position the torus.

Advantageously, said electrical circuit comprises means for conditioning the signal measured between the short-circuited output and the floating earth, in order to amplify this signal and to match the impedance according to the means for measuring the potential difference.

Advantageously, the device further comprises an energy-storage circuit supplied by the output of said inductive coupling means when it is not in a short-circuit state.

According to a variant, the device further comprises an additional inductive coupling means for supplying an energy-storage circuit.

Preferably, said energy storage means comprises two energy reserves in series connected to said inductive coupling means, only one of said reserves delivering a voltage supplying the device.

According to a variant, the device further comprises an electrical circuit for delivering a signal representing the current flowing in said conductor, connected to the output of said inductive coupling means.

According to another variant, the device comprises an analogue multiplexer delivering a first signal for current measurement, a second signal for voltage measurement and a third signal for supplying the device.

According to another variant, it comprises a plurality of inductive coupling means connected to said analogue multiplexer.

According to another variant, the device further comprises a wireless transmission means supplied by said energy-storage means.

The device also relates to a system comprising a plurality of contactless devices further comprising a circuit for analysing the information delivered by each of said devices, for locating on an electrical network the electrical loads causing the variations in said information.

Advantageously, the system according to the invention further comprises a general-consumption sensor measuring the variations in current and voltage of a general supply of the network comprising said devices and said electrical loads, said consumption sensor also supplying individual consumption information on each type of load, the system further comprising a circuit for analysing the correlations between the information supplied by said general-consumption sensor and said devices, and providing localised information on the consumption of the loads in the network.

### BRIEF DESCRIPTION OF THE DRAWINGS

The invention will be understood better from a reading of the following description concerning a non-limitative example embodiment, referring to the accompanying drawings, where:

FIG. 1 presents the overall block diagram of the device.

FIG. 2 presents an example of a process used for measuring the electrical quantities and transmitting the information.

FIG. 3 presents a non-exhaustive example of an electronic diagram of the system as described in this invention.

FIG. 4 presents examples of characterisation of the localised apparent powers estimated from the measurements of the device.

FIG. 5 presents examples of characterisation of the localised apparent powers estimated using a device for measuring the general consumption of the network studied.

### DETAILED DESCRIPTION

The present invention aims to measure the electrical consumption of an electrical subnetwork non-intrusively, that is to say without requiring either a power cut or additional wiring. The essential point of the invention lies in the ability of the system to extract its supply from the current transformer or transformers used for making the current measurement as well as its suitability for measuring the voltage with the same sensor.

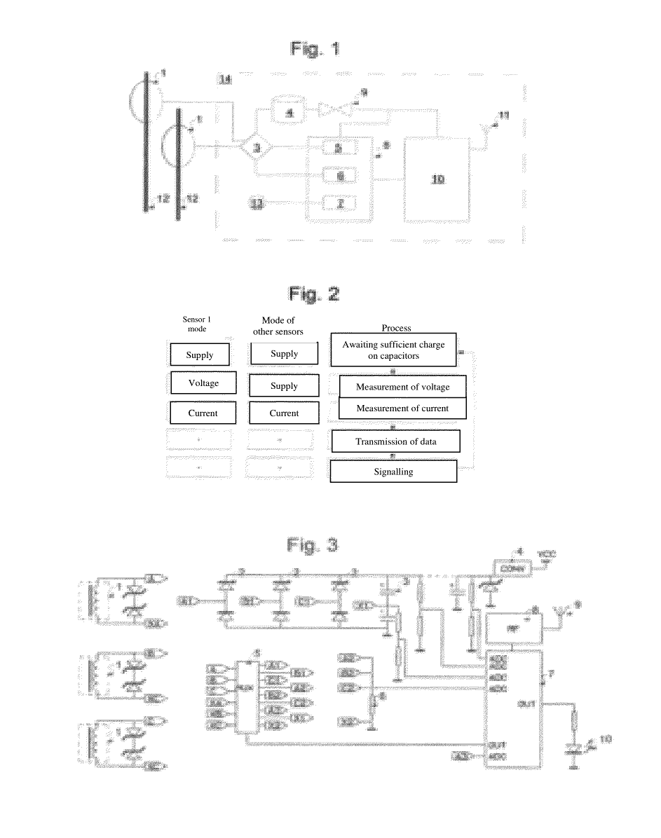

FIG. 1 presents the overall block diagram of the device.

### The Voltage Sensor

On an electrical network supplied with AC voltage, as is the case in France, measuring the electrical consumption of a plurality of items of equipment connected to a subnetwork requires measuring several quantities, at a minimum the waveforms of the current supplying the loads and the voltage presented at their terminals. These two quantities make it possible to calculate the instantaneous active power absorbed by the plurality of items of equipment and, by integration, the active energy consumed over a period of time.

The simple measurement of the current flowing in a cable therefore does not suffice to determine precisely the energy consumption since it presupposes the choice of the effective value of the voltage and of the power factor.

Ordinarily, measuring the voltage observed between two electrical conductors requires direct contact with this conductor, either by means of probes connected to an impedance of very high value, or using a voltage transformer providing galvanic isolation.

The present invention uses a current transformer (1) as a voltage sensor, in order to limit the number of sensors necessary for measuring the electrical consumption. A current transformer, the design of which will be detailed below, is connected so that its secondary circuit is in short-circuit. Seen from the outside, the current transformed is thus reduced to a single conductor, like an antenna. The winding of the secondary circuit, placed close to the primary conductor, interacts with the electrostatic field radiated by the live conductor and in its turn undergoes a variation in its electrical potential that can be measured by measurement of voltage between the secondary of the current transform short-circuited and a potential reference.

It has been demonstrated that, for a known positioning of the conductor vis-à-vis the winding representing the secondary circuit of a current transformer, the effective voltage and the peak to peak voltage of the signal issuing from the secondary circuit short-circuited is purely proportional to the amplitude of the voltage applied to the conductor being studied.

In a variant, the position of the conductor with respect to the secondary circuit of the current transformer is known.

In a variant, assuming that only the information on the phase difference between the waveform of the current and the waveform of the voltage is necessary, a capacitive sensor is used. A cable subjected to an alternating voltage with respect to a fixed potential radiates an electrical field that is almost independent of the current flowing therein. However, a capacitor is an electronic component where the voltage at its terminals is proportional to the intensity of the electric field in which it is immersed.

The electrical field radiated by said cable being largely dependent on the distance that separates the receiver from said cable, the amplitude of the voltage cannot be measured faithfully by these means. On the other hand, whatever its distance with respect to the cable, the capacitor has at its terminals a voltage the waveform of which is close to that of the voltage existing between said cable and earth, and the zero crossings of which are faithfully reproduced.

However, the phase difference between the waveform of the voltage and the waveform of the current can be determined by calculating the phase difference between the two fundamentals of the two waveforms involved. Considering the zero crossing of the signal supplied by the capacitor placed close to the cable as the phase reference, taking into account any constant bias, makes it possible to calculate the phase difference and consequently the active power absorbed by the loads connected downstream of this cable, the only possible error lying in the effective value of the voltage.

The device for making this measurement is composed of a capacitor, a connecting cable and a comparator. The capacitor may be of several kinds, the best results being obtained with ceramic capacitors of low value, below 100 pF, or opposing flat electrodes placed on either side of a dielectric support. The connecting cable, which must be as short as possible and have sufficient shielding not to suffer interference, connects the two terminals to said capacitor at the inputs of an electronic comparator, the output signal of which has two distinct values depending on whether the capacitor is biased in one direction or the other.

The digital signal issuing from the comparator is supplied to a microcontroller for subsequent processing.

Depending on the variant, the number of capacitive sensors used may vary. Either a capacitive sensor is used in a pair with each current sensor. Or a single capacitive sensor is used with a single current sensor, the other current sensors being positioned on cables with a known voltage. This is the case with all the cables in a single-phase installation, or with the three phases of a three-phase network. In the latter case, the phase differences are spaced apart by 120°.

### The Current Sensors

One or more current transformers (1) are used for measuring, in a non-intrusive and isolated manner, the waveform of the electric current passing through the cable. These sensors, based on a principle of conversion of the magnetic flux generated by the movement of electrical charges in a conductor referred to as the primary circuit and an electric current of proportional amplitude circulating in a winding referred to as the secondary circuit, are very much used in industry for measuring alternating currents.

In a variant, these transformers have a material with the right properties for channeling the magnetic flux and directing it to the secondary winding. This material may be ferrite.

In a variant, said material forms a ring around the primary circuit.

In a variant, said material forming a ring around the primary circuit is separated into two parts in order to enable it to be positioned around the primary circuit without requiring cutting and therefore opening of the primary circuit. This constitutes an advantage in the respect of non-intrusiveness.

In general terms, and in the case of correct sizing of the transformer, the current flowing in the secondary circuit is proportional to the primary circuit, the proportionality factor being the ratio of the number of turns made by the primary circuit compared with the number of turns made by the secondary circuit.

The general use of such a transformer is using it as a current sensor. The secondary circuit is then closed on a known load, for example a resistor, and the voltage arising at the terminals of this load represents an image of the current flowing in the secondary circuit and consequently the current flowing in the primary circuit.

These current sensors have the advantage of being passive, that is to say they do not require a supply source for delivering their output signal. This is not the case with Hall effect sensors, for example.

In a variant, the secondary circuits of the current transformers are equipped with protections limiting the overvoltage that may arise between their terminals.

### Current Measurement

In the system described here, the values of the current passing through the primary circuit are acquired by loading the secondary circuit of one or more current transformers with a resistor with a resistor with a known resistance. This resistor may bear the name shunt.

An analogue to digital converter (5) is used for converting the analogue signals of the voltage at the terminals of the shunt resistor.

An electronic conditioning circuit may be used for adapting the levels of the analogue signal so that it is suited to the input ranges of the analogue to digital converter.

In the case of the use of several current sensors, as is common for studying three-phase networks, a multiplexing stage (3) of the measuring channels is provided by switching the switches based on transistors. This multiplexing may be single-channel if there is no constraint of synchronism between channels, or multichannel.

### Microcontroller

A microcontroller (8) centralises the converted analogue measurements and the signals indicating the amplitude or sign of the voltages. This device makes the calculations required by the user and stores the results in a local memory.

### Wireless Communication

The communication of the system is provided by a radio communication stage (10) for remotely transmitting the harvested data without any hardware support. Non-limiting examples include one or more of the following technologies can be integrated: EnOcean, WMbus, 61oWPAN.

The communication device is at a minimum a transmitter (10), comprising an antenna (11) and a suitable electronic circuit. Any metal structure capable of radiating an electromagnetic field is considered to be an antenna.

In a variant, the communication device is a transceiver and changes its behaviour according to the data received.

In a variant, a light indicator (13) is used to indicate to the user the data transmission and reception phases.

### Autonomous Supply

The purpose of a system described here is not connected electrically and therefore adopts an autonomous supply system.

In order to ensure low cost price and longevity of the system, an energy reserve based on a battery of accumulators or cells is not sufficient.

A method for capturing the energy conveyed by the magnetic field radiated by the primary circuit is used. Each current transformer delivers to the secondary circuit a power that may be around a few tens of milliwatts. This power is dissipated in the form of heat when the current sensor is loaded onto a shut resistor.

The objective of this method is to extract, store and restore this energy. It is composed of one or more current transformers used to make the current measurement, optionally their protections against overvoltages, a voltage multiplying circuit, storage devices, a load balancing circuit and a voltage regulator.

The current generated by each current transformer is rectified by a pair of diodes, preferably of the Schottky type, and will alternately charge two groups of storage devices (4). The voltage available between the terminals of these storage devices is a DC voltage, the value of which is a multiple of the peak voltage delivered by the current transformers, where applicable protected against overvoltages.

In a variant, these storage devices are capacitors of the high-value aluminium type.

In a variant, the DC voltage available at the terminals of the storage devices is directed towards one or more DC to DC converters (9), the role of which is to adapt the voltage level according to the requirements of the other components implemented.

In a variant, the DC voltage available at the terminals of the storage devices is too high and is not compatible with the input range of inexpensive DC to DC converters. The advantage of achieving a high voltage at the terminals of the storage devices is to lead to storage of a high charge, this being proportional to the square of the voltage. The voltage supplied to the DC to DC converter is thus taken off at the terminals of only one of the two storage groups and its level will therefore be lower. A load balancing circuit is used to ensure that the voltage supplied to the DC to DC converter does not exceed its upper limit while protecting the storage devices from an excessively high individual voltage that may lead to their destruction. It is also used to maximise the input voltage of the DC to DC converter and thus to optimise its efficiency.

The load balancing circuit, if it is implemented, is composed of controllable switches that may be produced from transistors, acting on the discharge of one of the two storage groups in the circuit, the latter being connected to the voltage converter. The switches are controlled so as to direct the loads from one storage group to another according to the voltage present at the input of the converter. In order to guarantee the stability of the system, the current transformers are disconnected from the storage devices during these load-rebalancing phases.

In a variant, the voltage regulator has a very high efficiency and has the ability to deactivate itself in accordance with an instruction coming from another component.

In a variant, the microcontroller reads the values of the output and input voltages of the voltage regulator by means of analogue to digital converters in order to deploy a suitable strategy for managing the supply.

### Example Embodiment

FIG. 3 presents an example of a non-exhaustive electronic diagram of the system as described in this invention.

In one embodiment, three current sensors (1) of the current transformer type are connected to an electronic board, said electronic board having dimensions compatible with its positioning on the base of one of the current sensors. These current sensors are protected against overvoltages by diode clamps.

A multiplexer (5), produced from transistor switches and logic gates, redirects the signals issuing from the three current sensors, in accordance with the instructions transmitted by a microcontroller.

In a first case, the signals are directed to an energy storage device produced on the basis of two Schottky diodes (2) per current transformer providing the rectification and four identical capacitors (3) providing the storage. Said capacitors may be associated either in series during the charging phases or in parallel during the discharging phases. A high-efficiency chopping voltage regulator is implemented at the terminals of the capacitors in order to provide a regulated supply voltage to the components of the board.

In a second case, the signals are directed to a shunt resistor (6), the voltage at the terminals of which is connected to one of the analogue to digital converters of the microcontroller (7).

In a third case, the output of one of the current sensors is short-circuited and its voltage with respect to a floating earth is measured by an analogue to digital converter of the microcontroller (7).

The microcontroller controls the multiplexer and the storage device in accordance with the following steps.

First of all, the three sensors are connected simultaneously to the storage capacitors in series in order to increase the voltage at their terminals.

As soon as it is supplied by the DC to DC converter, that is to say as soon as the voltage at the terminals of the capacitors is higher than the minimum input voltage of the converter, the microcontroller makes regular measurements of the voltage level at the terminals of the capacitors.

As soon as this voltage exceeds a predefined threshold, corresponding to the energy storage necessary for performing the operations to follow, the microcontroller triggers the voltage measurement on the first measuring channel.

In a variant, all the measuring channels may be used for the purpose of voltage measurement.

Then, secondly, the capacitors are positioned in parallel in order to deliver the maximum amount of energy and a voltage acceptable for the DC to DC converter.

The signals from the current sensors are then directed to a shunt resistor in order to measure the current of the primary conductor being studied, for a predetermined number of periods.

Finally, the measured data are transmitted by the radio transmitter and a light indicator (10) is briefly switched on in order to indicate the success of the operation.

The current sensors are reconnected at the input of the storage device in order to recharge it by means of a new measurement and transmission sequence.

### Method for Locating the Consumption of the Loads in the Network

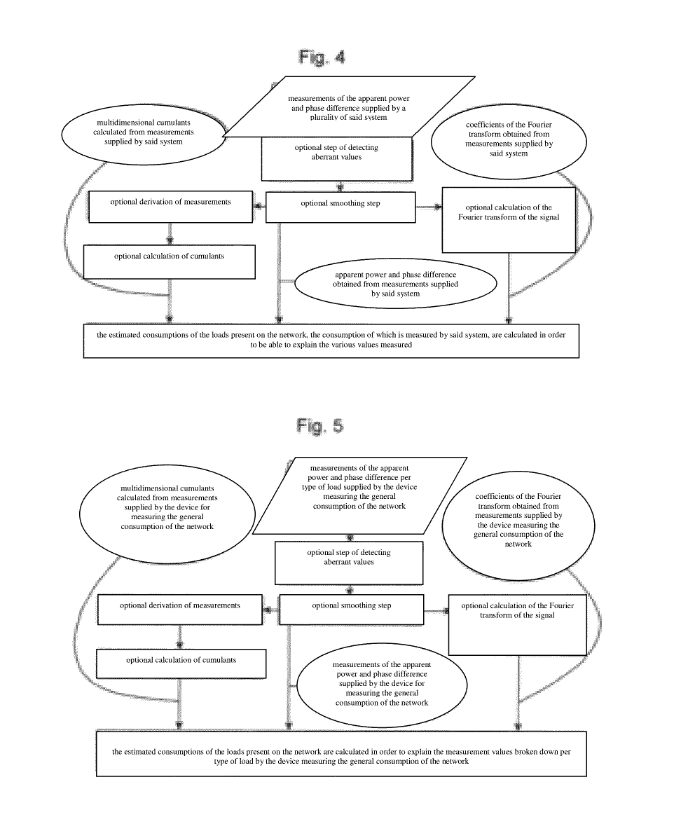

FIG. 4 presents examples of characterisation of the localised apparent powers estimated from the measurements of the device.

FIG. 5 presents examples of characterisation of the localised apparent powers estimated using a device measuring the general consumption of the network being studied.

The system described here can function coupled to a device for breaking down the signal characteristic of the electrical consumption of a building into an individual consumption for each type of load.

In which case said method provides an estimation of the individual consumption of each type of load present on the network the consumption of which it measures.

The purpose of the method described here is to use the apparent powers and phase differences between voltage and intensity measured by said system and the device for measuring the general consumption of the network, as well as external data obtained by means of a study of the behaviour of the loads according to their type, such as the ratio of the cumulants of the power and the mean of the power consumed according to the type of load, the ratio of the cumulants of the derivative of the power and the mean of the power and the Fourier transform of the measured power, as described below.

It is impossible here to make hypotheses on the statistical independence or on the absence of correlation between measurements supplied by a plurality of said system, or between individual consumption of each type of load on the network.

It is also impossible to form a hypothesis on synchronicity of the measurements supplied by a plurality of said system.

In doing this, it is possible to use here conventional algorithms for breaking down the sources, which are based mainly on a statistical independence between sources and secondarily on the synchronous character of the measurements.

Said method has available to it information on phase difference between voltage and intensity associated with a type of load. This phase difference remains constant for a given load, and identical whatever the location of the load on the network.

The method seeks to find a distribution of the consumption of the loads on the network satisfying the measurements of apparent powers and phase differences supplied by the plurality of said system and the device for measuring the general consumption of the network, broken down into types of load.

The search for an achievable solution of such a problem is a classic in scientific literature, and can be carried out for example by an initiation of a simplex problem, seeking to equalise the active and reactive parts of the powers, on the plurality of said system and for each load in the network studied.

In a variant, the method proceeds with a search for an achievable solution satisfying the above conditions and which minimises the sum of the absolute values of the derivatives of the consumptions per type of load located on the network. This type of problem is a problem of convex optimisation with linear constraints, a classic in the literature, and which can be solved by several methods, such as the internal points method.

In a variant, the method proceeds with a search for an achievable solution satisfying the above conditions of equality between active and reactive power, and satisfying conditions on the statistical properties of one or more multidimensional cumulants of the active and reactive powers measured by the plurality of said system and the device for measuring the general consumption of the network, broken down into types of load. The statistical properties on the cumulants of a type of load result from upstream studies on the distribution of the values of the cumulants of the active and reactive powers, in proportion to the value of these active and reactive powers. As a result these cumulants, divided by the mean of the apparent power, take values only in a restricted range of possible values. Since the cumulants are linear, we can seek achievable solutions the estimated apparent powers of which multiplied by envisageable cumulants can explain the cumulants of the active and reactive powers measured. The search for these solutions is a classic in the literature and can be obtained by an initiation of the simplex problem. This addition makes it possible to constrain the system further and to find a final estimation of the localised consumptions of the loads in the network.

In a variant, the method proceeds with a search for an achievable solution satisfying the above conditions not on certain cumulants of the active and reactive powers, but on certain cumulants of the derivatives of the active and reactive powers. In addition, these derivatives are characterisations of the signal that do not have any complex dependency on the smoothing of the signal by a sliding mean and have better linearity characteristics even when there are correlated signals present.

In a variant, said system provides the Fourier transform of the measured consumption. The method then seeks an achievable solution satisfying the above conditions, enhanced by conditions on the Fourier series of the measurements returned by said system and by the device for measuring the general consumption of the network. Each type of load having a breakdown of its unique consumption into a Fourier series, and the breakdown of a signal into Fourier series being a linear transformation, this addition of information makes it possible to very greatly constrain the system without making the problem to be solved more complex, by equalising the sum of the estimated Fourier transforms with those measured by said system on the one hand and with those measured for each type of load by the device for measuring the general consumption of the network.

In a variant, the method implements one of the above methods not on the measurements returned but on one of the measured signals smoothed for example by means of a sliding mean, and resampled, in order to have several measurements returned by each of said systems on each time step used.

In a variant, the method implements one of the above methods not on the returned measurements but on the returned measurements from which the aberrant values are extracted. This filtering improves the precision of all the methods based on a statistical analysis of the measurements. There exist numerous known public methods for extracting aberrant values; we can for example not take into account the extreme quantiles of a series of measurements.

In a variant, the method implements one of the above methods by solving the problems of seeking an achievable solution or seeking an optimum solution using heuristics such as the Markov Chain Monte Carlo method, which makes it possible to find an estimation of the apparent powers associated with a probability, depending on whether this estimation complies with the various conditions and minimises the function to be minimised.

1-11. (canceled)

12. A contactless device for characterising the electrical signal passing through an electrical conductor, comprising an inductive electromagnetic coupling means able to surround said conductor, said inductive electromagnetic coupling means further comprising means for short-circuiting the output of said inductive electromagnetic coupling means, said output being connected to an electronic circuit for measuring the potential difference with respect to a floating earth configured to deliver a signal representing the voltage between the segment of said conductor passing through the device, and a fixed potential reference.

13. The contactless device for characterising the electrical signal passing through an electrical conductor according to claim 12, wherein said electrical circuit comprises means for conditioning the signal measured between the short-circuited output and the floating earth, configured to amplify the signal and adapt the impedance according to the means for measuring the potential difference.

14. The contactless device for characterising the electrical signal passing through an electrical conductor according to claim 12, further comprising an energy-storage circuit supplied by the output of said inductive coupling means when it is not in a short-circuit state.

15. The contactless device for characterising the electrical signal passing through an electrical conductor according to claim 12, further comprising an additional inductive coupling means for supplying an energy-storage circuit.

16. The contactless device for characterising the electrical signal passing through an electrical conductor according to claim 14, wherein said energy-storage means comprises two energy reserves in series connected to said inductive coupling means, only one of said reserves delivering a voltage supplying said device.

17. The contactless device for characterising the electrical signal passing through an electrical conductor according to claim 12, further comprising an electrical circuit for delivering a signal representing the current flowing in said conductor, connected to the output of said inductive coupling means.

18. The contactless device for characterising the electrical signal passing through an electrical conductor according to claim 12, further comprising an analogue multiplexer delivering a first signal for the current measurement, a second signal for the voltage measurement and a third signal for the supply to the device.

19. The contactless device for characterising the electrical signal passing through an electrical conductor according to claim 18, further comprising a plurality of inductive coupling means connected to said analogue multiplexer.

20. The contactless device for characterising the electrical signal passing through an electrical conductor according to claim 12, further comprising a wireless transmission means supplied by an energy-storage means.

21. A system comprising a plurality of contactless devices according to claim 12, comprising a circuit for analysing the information delivered by each of said devices, for locating on an electrical network the electrical loads causing the variations in said information.

22. The system according to claim 21, further comprising a general consumption sensor measuring the variations in current and voltage of a general supply of the network comprising said devices and said electrical loads, said consumption sensor also supplying individual consumption information on each type of load, the system further comprising a circuit for analysing the correlations between the information supplied by said general consumption sensor and said devices, and supplying localised information on the consumption of the loads in the network.
